(19) United States
(12) Patent Application Publication
(10) Pub. No.: US 2010/0232135 A1
(43) Pub. Date: Sep. 16, 2010

(54) PHOTOSYNTHESIS INHIBITING LIGHT SOURCE AND ILLUMINATING DEVICE THAT USES THE SAME

(76) Inventors: Kawamura Munehiro, Yamaguchi-shi (JP); Yoshimura Kazumasa, Yamaguchi-shi (JP); Ano Yuji, Yamaguchi-shi (JP); Nagayama Kazunori, Yamaguchi (JP)

Correspondence Address: Muramatsu & Associates, 114 Pacifica Suite 310, Irvine, CA, 92618, US

(21) Appl. No.: 12/734,769

(22) PCT Filed: Nov. 21, 2008
(86) PCT No.: PCT/JP2008/071269

§ 371 Date: May 20, 2010

(30) Foreign Application Priority Data
Nov. 23, 2007 (JP) 2007-303804

(51) Int. Cl. F21V 9/16; H01J 1/62; H01L 33/44

(52) U.S. Cl. 362/84; 313/483; 257/98; 257/E33.061; 257/E33.067

(57) ABSTRACT

A photosynthesis inhibiting light source that emits substantially white light that does not exert an adverse influence on the human body while inhibiting/stunting the growth and propagation of photosynthetic organisms. photosynthesis inhibiting light source includes a semiconductor layer that emits near-ultraviolet light and at least one kind of fluorescent substance that emits light by being excited by the near-ultraviolet light. The near-ultraviolet light includes ultraviolet light having a light emission band in wavelengths of 300 to 380 nm and violet light having a light emission band in wavelengths of 380 to 400 nm. The mixed light of the near-ultraviolet light and light emitted by the at least one kind of fluorescent substance is substantially white.

### TECHNICAL FIELD

This invention relates to a photosynthesis inhibiting light source that inhibits or stunts the growth of photosynthetic organisms, and relates to an illuminating device that uses this light source.

### BACKGROUND ART

Conventionally, a fluorescent lamp, a sodium lamp, a mercury lamp, etc., have been used to illuminate the inside of a cave located in, for example, a sightseeing area, and these lamps (i.e., light sources) include light that contributes to the growth of photosynthetic organisms, and therefore there has been a fear that photosynthetic organisms, which cannot grow in such a cave under normal circumstances, will be propagated or multiplied, thus destroying an ecosystem in the cave.

On the other hand, in order to observe the inside of a cave in, for example, a sightseeing area or ensure the safety of a person walking in the cave, it is indispensable and unavoidable to illuminate the inside of the cave.

There has been a possible method according to which photosynthetic organisms that have grown or have flourished on a spot illuminated with light in the cave are removed by a physical means or a chemical means, such as a chemical agent. However, this method has had a fear that both the physical means and the chemical means will damage wall surfaces of the cave or a fear that water in the cave will be polluted with a cleaning solution.

Therefore, some inventions relative to a light source used to, for example, stunt the growth of organisms or used to inhibit photosynthesis have been disclosed in order to overcome the disadvantages mentioned above.

Patent Literature 1 discloses an invention that is titled “FLASHING DISCHARGE LAMP FOR STERILIZATION AND STERILIZATION METHOD” and that relates to a flashing discharge lamp for sterilization, which is capable of obtaining rays of light having high radiant intensity in a far ultraviolet region and hence obtaining an adequately great sterilizing effect and capable of having a long operating life, and that relates to a sterilization method according to which a sterilizing effect can be obtained with high efficiency.

The invention disclosed by Patent Literature 1 relates to a flashing discharge lamp for sterilization characterized in that at least one kind of rare gas selected from the group consisting of xenon, krypton, and argon and either antimony or an antimony compound are fully contained in a discharge container, and relates to a sterilization method of illuminating a to-be-treated target with light emitted from the flashing discharge lamp for sterilization.

According to the invention disclosed by Patent Literature 1, antimony or an antimony compound is contained in the discharge container, and therefore it is possible to reach a state in which a radiation spectrum in a far ultraviolet region by means of antimony predominates over a radiation spectrum by means of rare gas, and is possible to obtain light having a wavelength contributing to sterilization in the far ultraviolet region with high radiant intensity, thus making it possible to obtain an adequately high sterilizing effect with respect to the to-be-treated target.

Patent Literature 2 discloses an invention that is titled “LIGHTING APPARATUS FOR AQUARIUM AND AQUARIUM PROVIDED WITH LIGHTING APPARATUS” and that relates to a lighting apparatus for an aquarium that inhibits the generation of algae adhering to the wall surface of the aquarium without using a chemical agent and that suitably controls the growth of water plants, and relates to an aquarium provided with the lighting apparatus.

The invention disclosed by Patent Literature 2 is a lighting apparatus used to illuminate an ornamental aquarium with light, and is characterized by using a light source that emits green light having an emission peak wavelength in the range of wavelengths ranging from 500 nm to 600 nm.

According to the lighting apparatus of the invention disclosed by Patent Literature 2, green light having an emission peak wavelength in the range of wavelengths from 500 nm to 600 nm is emitted, and, as a result, advantageously, the generation of algae is inhibited by the action of this light, and water plants are prevented from growing excessively.

As a result, a chemical agent is not required to be put into the aquarium in order to inhibit the generation of algae, and therefore the quality of water in the aquarium can be prevented from being changed, and there is no fear of exerting an adverse influence upon aquarium fishes and water plants. In other words, water plants are only controlled to grow suitably, and have no fear of being adversely influenced, and therefore it is possible to maintain a form that has once undergone trimming for a long time, and, advantageously, a layout appearance is not disarranged. Additionally, it is possible to maintain the transparency or translucency of the aquarium for a long time.

Patent Literature 1: Japanese Published Unexamined Patent Application No. 2001-68057

Patent Literature 2: Japanese Published Unexamined Patent Application No. 2003-169566

### DISCLOSURE OF INVENTION

### Problems to be Solved by the Invention

However, if the “flashing discharge lamp for sterilization” of Patent Literature 1 is used as an illuminating device in a cave, the flashing discharge lamp has the conventional problem of having a high possibility that its light in the far ultraviolet region will also harm the human body and hence being unsuitable for illumination at a place to be visited by many people although the flashing discharge lamp can probably inhibit the growth or propagation of photosynthetic organisms in the cave by its high sterilizing effect. Additionally, the flashing discharge lamp has the conventional problem of having a great fear that an adverse influence will be exerted upon rare organisms living in the cave.

Still additionally, the “flashing discharge lamp for sterilization” of Patent Literature 1 emits light in the far ultraviolet region that is outside the visible region, and therefore a to-be-illuminated target cannot be brilliantly illuminated by the discharge lamp because the light of the discharge lamp is unperceivable to the human eye, and there has been a possibility that this lamp will be unsuitable as an illuminating device.

Still additionally, a conceivable method is to concomitantly use the “flashing discharge lamp for sterilization” of Patent Literature 1 together with another light source, such as a well-known fluorescent lamp, a sodium lamp, or a mercury lamp. In detail, a target is illuminated by a light source, such as a well-known fluorescent lamp, a sodium lamp, or a mercury lamp, in a time zone in which tourists enter the cave, whereas the target is sterilized by the “flashing discharge lamp for sterilization” of Patent Literature 1 in a time zone, such as nighttime, in which tourists do not enter the cave. However, there has been a problem in the fact that an increase in size of the illuminating device brings about complexity of maintenance, and electricity costs become high for sterilization illumination.

The invention disclosed by Patent Literature 2 mentioned above relates to a lighting apparatus used for an aquarium, and relates to an aquarium provided with a lighting apparatus. Although this aquarium is required to prevent the generation of algae, it is undesirable to adversely affect the growth of aquarium fishes, and therefore it has been inappropriate to prevent the generation of algae by use of ultraviolet light or far-ultraviolet light that has a high sterilizing effect.

Additionally, if the inside of the aquarium is illuminated only with green light, there has been a possibility that the inside of the aquarium cannot be brilliantly illuminated with this light although the generation of algae can be delayed or the growth of water plants can be halted.

If green light is used concomitantly with a white light source, such as a fluorescent lamp, the green light will advantageously halt the growth or propagation of photosynthetic organisms whereas the white light source, such as a fluorescent lamp, will act to quicken the growth or propagation of such photosynthetic organisms. Therefore, if an illuminating device is formed by combining these light sources together, there has been a high possibility that the growth or propagation of these organisms cannot also be fully inhibited although the possibility of quickening the growth or propagation thereof is probably low.

The present invention has been made in consideration of these conventional circumstances, and therefore it is an object of the present invention to provide a white light source that is capable of brightly illuminating a to-be-illuminated target while inhibiting/stunting the growth or propagation of photosynthetic organisms and that has no fear of exerting an adverse influence upon the human body, and provide an illuminating device that uses this white light source.

### Means for Solving the Problems

A photosynthesis inhibiting light source that is an invention according to claim 1 is characterized by comprising a semiconductor layer that emits near-ultraviolet light and at least one kind of fluorescent substance that emits light by being excited by the near-ultraviolet light, wherein the near-ultraviolet light includes ultraviolet light having a light emission band in wavelengths of 300 to 380 nm and violet light having a light emission band in wavelengths of 380 to 400 nm, wherein the at least one kind of fluorescent substance does not include a combination of a fluorescent substance that has a light emission peak in wavelengths of 430 to 490 nm and that emits blue light and a fluorescent substance that has a light emission peak in wavelengths of 640 to 680 nm and that emits red light, and wherein mixed light of the near-ultraviolet light and light emitted by the at least one kind of fluorescent substance is substantially white.

In the thus structured photosynthesis inhibiting light source, the semiconductor layer has the process of emitting near-ultraviolet light. Additionally, ultraviolet light having a light emission band in wavelengths of 300 to 380 nm included in this near-ultraviolet light has the process of inhibiting/stunting the growth and propagation of photosynthetic organisms while changing the structure of protein with which the surface of photosynthetic organisms is covered or while obstructing the replication of DNA of photosynthetic organisms.

The “photosynthetic organisms” mentioned in this description denote general organisms that have chlorophyll and have a production capacity to produce available-to-organisms organic compounds from H₂O and CO₂ while using light energy. Examples of these organisms include seed plants, fern, moss, algae, fungi, and bacilli.

Additionally, in this description, light in a region in which the peak position of its wavelength is shorter than 380 nm is referred to as ultraviolet light, light having a light emission peak in wavelengths of 380 to 400 nm is referred to as violet light, light having a light emission peak in wavelengths of 400 to 430 nm is referred to as blue-violet light, light having a light emission peak in wavelengths of 430 to 490 nm is referred to as blue light, light having a light emission peak in wavelengths of 490 to 570 nm is referred to as green light, light having a light emission peak in wavelengths of 570 to 600 nm is referred to as yellow light, light having a light emission peak in wavelengths of 600 to 640 nm is referred to as orange light, light having a light emission peak in wavelengths of 640 to 680 nm is referred to as red light, and light having a light emission peak in wavelengths of 300 to 400 nm is referred to as near-ultraviolet light.

Additionally, the at least one kind of fluorescent substance excited by near-ultraviolet light can be specified as being any fluorescent substance except for a combination of a fluorescent substance that emits blue light and that has a light emission peak in wavelengths of 430 to 490 nm and a fluorescent substance that has a light emission peak in wavelengths of 640 to 680 nm and that emits red light, more preferably, except for a combination of a fluorescent substance that has a light emission peak in wavelengths of 430 to 490 nm and that emits blue light and a fluorescent substance that has a light emission peak in wavelengths of 600 to 680 nm and that emits orange-to-red light, still more preferably, except for a fluorescent substance that has a light emission peak in wavelengths of 640 to 680 nm and that emits red light, very much more preferably, except for a fluorescent substance that has a light emission peak in wavelengths of 600 to 680 nm and that emits orange-to-red light. The reason is that it is known that both of blue light having a light emission peak in wavelengths of 430 to 490 nm and red light having a light emission peak in wavelengths of 640 to 680 nm, in more detail, both of blue light having a light emission peak in wavelengths of 430 to 490 nm and orange-to-red light having a light emission peak in wavelengths of 600 to 680 nm are required to promote the normal growth of photosynthetic organisms.

Additionally, the reason is that it is known as a research result that, in particular, red light having a light emission peak in wavelengths of 640 to 680 nm, in more detail, orange-to-red light having a light emission peak in wavelengths of 600 to 680 nm contributes directly to a photosynthetic reaction performed by chlorophyll that is present inside the body of each photosynthetic organism, i.e., to the production of available-to-organisms organic compounds from H₂O and CO₂. (see Application of LED to plant cultivation, Tanaka Fumihiro et al., OPTRONICS No. 12, pp. 134-140 (1998), Plant cultivation using semiconductor laser diode, Kan Hirofumi et al., OPTRONICS No. 12, pp. 129-133, Plant cultivation using three-color RGB high-intensity LEDs and growth sensing, Okamoto Kensei et al., Applied physics, Vol. 68, No. 12, pp. 156-160 (1999), Japanese Published Unexamined Patent Application No. 9-98.)

According to the research result, although red light having a light emission peak in wavelengths of 640 to 680 nm is greater in the contribution to a photosynthetic reaction, the peak of absorption by chlorophyll is found near a wavelength of 640 nm or 600 nm. Therefore, it is preferable to except a combination of fluorescent substances that have a light emission peak in wavelengths of 600 to 680 nm including the above-mentioned light emission peaks and that emit orange-to-red light.

Therefore, it is possible to have the process of obstructing the contribution of light emitted from at least one kind of fluorescent substance to the normal growth of photosynthetic organisms by excepting a combination of blue light having a light emission peak in wavelengths of 430 to 490 nm and red light having a light emission peak in wavelengths of 640 to 680 nm from the light source, more preferably, by excepting a combination of blue light having a light emission peak in wavelengths of 430 to 490 nm and orange-to-red light having a light emission peak in wavelengths of 600 to 680 nm from the light source.

Additionally, the invention has the process of obstructing the contribution of light emitted from at least one kind of fluorescent substance directly to a photosynthetic action inside the body of each photosynthetic organism especially by excepting red light having a light emission peak in wavelengths of 640 to 680 nm from the light source, more preferably, by excepting orange-to-red light having a light emission peak in wavelengths of 600 to 680 nm from the light source.

Additionally, substantially white light is made by mixing together at least one kind of light emitted from at least one kind of fluorescent substance and violet light having a light emission band in wavelengths of 380 to 400 nm included in near-ultraviolet light, and, as a result, it is possible to have the process of brightly illuminating a to-be-illuminated target with the substantially white light without giving a feeling of strangeness to the human eye.

The term “substantially white (light)” mentioned in CLAIMS and DESCRIPTION denotes white (light) including bluish white, greenish white, yellowish white, or violetish white in a chromaticity diagram according to JIS standards.

A photosynthesis inhibiting light source that is an invention according to claim 2 is characterized by comprising a semiconductor layer that emits near-ultraviolet light and at least two kinds of fluorescent substances that emit light by being excited by the near-ultraviolet light, wherein the near-ultraviolet light includes ultraviolet light having a light emission band in wavelengths of 300 to 380 nm, wherein the at least two kinds of fluorescent substances do not include a combination of a fluorescent substance that has a light emission peak in wavelengths of 430 to 490 nm and that emits blue light and a fluorescent substance that has a light emission peak in wavelengths of 640 to 680 nm and that emits red light, and wherein mixed light of at least two kinds of light emitted by the at least two kinds of fluorescent substances is substantially white.

In the thus structured photosynthesis inhibiting light source, the semiconductor layer has the process of emitting near-ultraviolet light. Ultraviolet light having a light emission band in wavelengths of 300 to 380 nm included in this near-ultraviolet light has the process of changing the structure of protein with which the surface of photosynthetic organisms is covered, and obstructing the replication of DNA of photosynthetic organisms, and hence inhibiting/stunting the growth and propagation of photosynthetic organisms.

Additionally, the invention has the process of obstructing the contribution of at least two kinds of light emitted from the at least two kinds of fluorescent substances to the normal growth of photosynthetic organisms by adopting a structure in which the at least two kinds of fluorescent substances excited by the near-ultraviolet light are any fluorescent substances except for a combination of a fluorescent substance that has a light emission peak in wavelengths of 430 to 490 nm and that emits blue light and a fluorescent substance that has a light emission peak in wavelengths of 640 to 680 nm and that emits red light, more preferably, except for a combination of a fluorescent substance that has a light emission peak in wavelengths of 430 to 490 nm and that emits blue light and a fluorescent substance that has a light emission peak in wavelengths of 600 to 680 nm and that emits orange-to-red light.

Additionally, the invention has the process of obstructing the contribution of at least two kinds of light emitted from the at least two kinds of fluorescent substances directly to a photosynthetic action inside the body of each photosynthetic organism especially by adopting a structure in which the at least two kinds of fluorescent substances excited by the near-ultraviolet light are any fluorescent substances except for a fluorescent substance that has a light emission peak in wavelengths of 640 to 680 nm and that emits red light, more preferably, except for a fluorescent substance that has a light emission peak in wavelengths of 600 to 680 nm and that emits orange-to-red light.

Additionally, substantially white light is made by mixing rays of light emitted from the at least two kinds of fluorescent substances together, thereby having the process of brightly illuminating a to-be-illuminated target with the substantially white light without giving a feeling of strangeness to the human eye.

A photosynthesis inhibiting light source according to claim 3 is the photosynthesis inhibiting light source according to claim 1, and is characterized in that the fluorescent substance is a fluorescent substance that has a light emission peak in wavelengths of 550 to 570 nm and that emits green light.

The thus structured photosynthesis inhibiting light source has the process of supplying light that can hardly contribute to photosynthesis to photosynthetic organisms adhering to or growing epiphytically on a to-be-illuminated target especially by using only a fluorescent substance that has a light emission peak in wavelengths of 550 to 570 nm and that emits green light as the fluorescent substance, in addition to the same process as the invention of claim 1.

Additionally, it is possible to have the process of making mixed light obtained by being mixed with near-ultraviolet light into substantially white light while using the smallest number of kind of, i.e., only one kind of fluorescent substance by selecting green light that is in a complementary relationship with violet light having a light emission band in wavelengths of 380 to 400 nm included in near-ultraviolet light as the light emitted from the fluorescent substance.

A photosynthesis inhibiting light source according to claim 4 is the photosynthesis inhibiting light source according to claim 2, and is characterized in that the fluorescent substances are a fluorescent substance that has a light emission peak in wavelengths of 430 to 490 nm and that emits blue light and a fluorescent substance that has a light emission peak in wavelengths of 570 to 600 nm and that emits yellow light, respectively.

The thus structured photosynthesis inhibiting light source has the process of supplying light that can hardly contribute to the normal growth of photosynthetic organisms adhering to or growing epiphytically on a to-be-illuminated target especially by using two kinds of fluorescent substances, i.e., by using a fluorescent substance that has a light emission peak in wavelengths of 430 to 490 nm and that emits blue light and a fluorescent substance that has a light emission peak in wavelengths of 570 to 600 nm and that emits yellow light, respectively, as the fluorescent substances, in addition to the same process as the invention of claim 2.

Additionally, it is possible to have the process of mixing only rays of light emitted from the fluorescent substances together into substantially white light while minimizing the number of kinds of fluorescent substances by selecting blue light having a light emission peak in wavelengths of 430 to 490 nm and yellow light having a light emission peak in wavelengths of 570 to 600 nm, which stand in a complementary relationship, as rays of light emitted from the fluorescent substances.

A photosynthesis inhibiting illuminating device that is an invention according to claim 5 is characterized by comprising at least one photosynthesis inhibiting light source according to any one of claim 1 to claim 4.

The thus structured photosynthesis inhibiting illuminating device comprises the photosynthesis inhibiting light source according to any one of claim 1 to claim 4, and has the same process as the invention of any one of claim 1 to claim 4.

A photosynthesis inhibiting illuminating device that is an invention according to claim 6 is the photosynthesis inhibiting illuminating device of claim 5, and is characterized by further comprising an optical diffuser disposed on a side toward which light of the photosynthesis inhibiting light source is emitted.

The thus structured photosynthesis inhibiting illuminating device has the process of allowing the optical diffuser to promote the diffusion of light emitted from the photosynthesis inhibiting light source, in addition to the same process as the invention of claim 5.

A photosynthesis inhibiting illuminating device that is an invention according to claim 7 is the photosynthesis inhibiting illuminating device of claim 6, and is characterized in that the fluorescent substance is contained in or is allowed to adhere to the optical diffuser.

The thus structured photosynthesis inhibiting illuminating device has the effect of allowing the optical diffuser to convert part of the near-ultraviolet light emitted from the semiconductor layer into light having a specific wavelength region by means of the fluorescent substance contained in the optical diffuser or adhering to surface of the optical diffuser, and then mixing the resulting light and near-ultraviolet light together or mixing rays of light that are emitted from the fluorescent substances and that have specific wavelength regions together, thus making substantially white light, in addition to the same process as the invention of claim 6.

### EFFECTS OF THE INVENTION

According to the invention of claim 1 of the present invention, violet light included in near-ultraviolet light is mixed with at least one kind of light, which does not contribute to the normal growth of photosynthetic organisms or which can hardly contribute to photosynthesis, emitted from a fluorescent substance, thereby having the effect of being capable of generating substantially white light that does not contribute to the normal growth of photosynthetic organisms or substantially white light that can hardly contribute to photosynthesis.

Additionally, ultraviolet light included in near-ultraviolet light emitted from a semiconductor layer changes the structure of protein with which the surface of photosynthetic organisms is covered or obstructs the replication of DNA of photosynthetic organisms, thereby having the effect of inhibiting/stunting the growth and propagation of photosynthetic organisms.

Therefore, the invention of claim 1 has the effect of being capable of generating substantially white light capable of brightly illuminating a to-be-illuminated target while inhibiting/stunting the growth and propagation of photosynthetic organisms from one light source.

As a result, light emitted from the photosynthesis inhibiting light source of claim 1 is projected onto the to-be-illuminated target, thereby having the effect of being capable of brightly illuminating the to-be-illuminated target with substantially white light and the effect of being capable of inhibiting the growth/propagation of photosynthetic organisms, which cannot grow at the to-be-illuminated target under normal circumstances, while inhibiting/stunting the growth of photosynthetic organisms at the place onto which the substantially white light is projected.

Therefore, when the inside of a cave is illuminated by the photosynthesis inhibiting light source of claim 1, the effect of being capable of suitably maintaining an ecosystem in the cave is achieved.

According to the invention of claim 2 of the present invention, at least two kinds of rays of light, which do not contribute to the normal growth of photosynthetic organisms or which can hardly contribute to photosynthesis, emitted from fluorescent substances are mixed together, thereby having the effect of being capable of generating substantially white light that does not contribute to the normal growth of photosynthetic organisms or that can hardly contribute to the growth and propagation of photosynthetic organisms.

Additionally, ultraviolet light included in near-ultraviolet light emitted from the semiconductor layer changes the structure of protein with which the surface of photosynthetic organisms is covered or obstructs the replication of DNA of photosynthetic organisms, thereby having the effect of inhibiting/stunting the growth and propagation of photosynthetic organisms.

Therefore, the invention of claim 2 has the effect of being capable of generating substantially white light capable of brightly illuminating a to-be-illuminated target while inhibiting/stunting the growth and propagation of photosynthetic organisms from one light source.

As a result, light emitted from the photosynthesis inhibiting light source of claim 2 is projected onto the to-be-illuminated target, thereby having the effect of being capable of brightly illuminating the to-be-illuminated target with substantially white light and the effect of being capable of inhibiting the growth/propagation of photosynthetic organisms, which cannot grow at the to-be-illuminated target under normal circumstances, while inhibiting/stunting the growth of photosynthetic organisms at the place onto which the substantially white light is projected.

Therefore, when the inside of a cave is illuminated by the photosynthesis inhibiting light source of claim 2, the effect of being capable of suitably maintaining an ecosystem in the cave is achieved.

The invention of claim 3 of the present invention is characterized in that the fluorescent substance is only a fluorescent substance that has a light emission peak in wavelengths of 550 to 570 nm and that emits green light, and a combination of this fluorescent substance and a semiconductor layer that emits near-ultraviolet light is used, thereby having the effect of being capable of setting the number of kinds of fluorescent substances required to fulfill the same effect as the invention of claim 1 at one that is the smallest number.

As a result, it is possible to have the effect of being capable of making substantially white light emitted from the photosynthesis inhibiting light source of claim 3 into substantially white light that has sharpness and less dullness.

Additionally, the photosynthesis inhibiting light source of claim 3 has the effect of being capable of improving reliability by its simple structure and the effect of being capable of reducing its production cost by low cost of raw materials.

The invention of claim 4 of the present invention is characterized in that the fluorescent substances are two kinds of fluorescent substances, i.e., a fluorescent substance that has a light emission peak in wavelengths of 430 to 490 nm and that emits blue light and a fluorescent substance that has a light emission peak in wavelengths of 570 to 600 nm and that emits yellow light, thereby having the effect of being capable of setting the number of kinds of fluorescent substances used when substantially white light is made by using only rays of light emitted from fluorescent substances at two.

As a result, the same effect as the invention of claim 2 is achieved. Moreover, the number of kinds of fluorescent substances to be used is small, thereby having the effect of being capable of making substantially white light emitted from the photosynthesis inhibiting light source of claim 4 into substantially white light that has sharpness and less dullness.

Additionally, the photosynthesis inhibiting light source of claim 4 has the effect of being capable of improving reliability by its simple structure and the effect of being capable of reducing its production cost by low cost of raw materials.

The invention of claim 5 of the present invention is a photosynthesis inhibiting illuminating device comprising at least one photosynthesis inhibiting light source according to any one of claim 1 to claim 4, and has the same effect as the invention of each of claims 1 to 4.

The invention of claim 6 of the present invention is characterized by further comprising an optical diffuser, thereby having the effect of achieving the advancement of the diffusion of light emitted from the photosynthesis inhibiting light source, and hence being capable of illuminating a wide range with the diffused light, in addition to the same effect as the invention of claim 5.

The invention of claim 7 of the present invention is characterized in that the fluorescent substance is contained in or is allowed to adhere to the optical diffuser, thereby enabling the fluorescent substance and the semiconductor layer emitting near-ultraviolet light to be disposed individually and separately from each other, hence having the effect of being capable of producing a photosynthesis inhibiting illuminating device that has the same effect as the invention of claim 6 by use of a ready-made LED that emits near-ultraviolet light.

As a result, it is possible to have the effect of being capable of greatly reducing the production cost of a photosynthesis inhibiting illuminating device that has the same effect as the invention of claim 6.

### BRIEF DESCRIPTION OF THE DRAWINGS

FIG. 1 is a sectional view of a photosynthesis inhibiting light source according to a first embodiment (Embodiment 1) of the present invention.

FIG. 2 is a sectional view of a photosynthesis inhibiting light source according to a second embodiment (Embodiment 2) of the present invention.

FIG. 3 is a conceptual diagram of a photosynthesis-inhibiting illuminating device according to a third embodiment (Embodiment 3) of the present invention.

FIG. 4 is a sectional view of the photosynthesis inhibiting illuminating device according to the third embodiment of the present invention.

### DESCRIPTION OF SIGNS

1 . . . Photosynthesis inhibiting light source
1a . . . Photosynthesis inhibiting light source
1b . . . Photosynthesis inhibiting light source
2a . . . Frame
2b . . . Frame
3 . . . Substrate
4 . . . Buffer layer
5 . . . Semiconductor layer
6a . . . Wire
6b . . . Wire
7 . . . Sealing material
8 . . . Fluorescent substance
9 . . . Lens
10 . . . Near-ultraviolet light
11 . . . Violet light
12 . . . Green light
13 . . . Mixed light (substantially white light)
14a . . . Fluorescent substance
14b . . . Fluorescent substance
15 . . . Blue light
16 . . . Yellow light
17 . . . Photosynthesis inhibiting illuminating device
18 . . . Board
19 . . . Planar light source
20 . . . Reflector
21 . . . Optical diffuser
22a . . . Leg
22b . . . Leg
23 . . . Mixture light (substantially white light)
24 . . . Housing

### BEST MODE FOR CARRYING OUT THE INVENTION

Referring to first to third embodiments, a detailed description will be given of a photosynthesis inhibiting light source according to the best mode of the present invention and a photosynthesis inhibiting illuminating device that uses this light source.

### Embodiment 1

As described above, until now, from various experiments and researches, it has been known that both blue light having a light emission peak in wavelengths of 430 to 490 nanometers (nm) and red light having a light emission peak in wavelengths of 640 to 680 nm, in more detail, both blue light having a light emission peak in wavelengths of 430 to 490 nm and orange-to-red light having a light emission peak in wavelengths of 600 to 680 nm are required to allow photosynthetic organisms to grow normally.

Additionally, it has been known from various experiments and researches that red light having a light emission peak in wavelengths of 640 to 680 nm, in more detail, orange-to-red light having a light emission peak in wavelengths of 600 to 680 nm is required especially when photosynthesis is carried out inside the body of a photosynthetic organism.

Therefore, the present inventors have found that the normal growth of photosynthetic organisms can be stunted by mixing and emitting rays of light having specific wavelength regions, except for a combination of blue light having a light emission peak in wavelengths of 430 to 490 nm and red light having a light emission peak in wavelengths of 640 to 680 nm, more preferably, except for a combination of blue light having a light emission peak in wavelengths of 430 to 490 nm and orange-to-red light having a light emission peak in wavelengths of 600 to 680 nm. In particular, the present inventors have found that a photosynthetic action itself can be inhibited so as to halt or inhibit the growth and propagation of photosynthetic organisms by mixing and emitting rays of light having specific wavelength regions, except for red light having a light emission peak in wavelengths of 640 to 680 nm, more preferably, except for orange-to-red light having a light emission peak in wavelengths of 600 to 680 nm, and have found that a to-be-illuminated target can be brightly illuminated without giving a feeling of strangeness to the human eye if such mixed light is substantially white light.

Additionally, the present inventors have found that, if a fluorescent substance excited by near-ultraviolet light is used as a means for obtaining light having specific wavelength regions, except for a combination of blue light having a light emission peak in wavelengths of 430 to 490 nm and red light having a light emission peak in wavelengths of 640 to 680 nm, more preferably, except for a combination of blue light having a light emission peak in wavelengths of 430 to 490 nm and orange-to-red light having a light emission peak in wavelengths of 600 to 680 nm, still more preferably, except for red light having a light emission peak in wavelengths of 640 to 680 nm, very much more preferably, except for orange-to-red light having a light emission peak in wavelengths of 600 to 680 nm, the growth and propagation of photosynthetic organisms can be inhibited and stunted more reliably by allowing ultraviolet light (having a light emission band in wavelengths of 300 to 380 nm) that is included in near-ultraviolet light that has passed through without being absorbed by a fluorescent substance to change the structure of protein with which the surface of photosynthetic organisms is covered or to obstruct the replication of DNA of photosynthetic organisms, in addition to the advantage of illuminating the above-mentioned to-be-illuminated target.

Additionally, this near-ultraviolet light does not exert an adverse influence on the human body, and hence is usable as an illuminating light source, and is safe.

Therefore, the present invention provides a light source capable of inhibiting/stunting the growth and propagation of photosynthetic organisms by combining and using a semiconductor layer that emits near-ultraviolet light and a fluorescent substance that is excited by near-ultraviolet light, by mixing violet light having a light emission band in wavelengths of 380 to 400 nm included in near-ultraviolet light and light having a specific wavelength region emitted from at least one fluorescent substance or by mixing rays of light having at least two kinds of specific wavelength regions emitted from at least two kinds of fluorescent substances and, as a result, making substantially white light suitable for illumination, and by illuminating a to-be-illuminated target with a combination of substantially white light that can hardly contribute to the growth and propagation of photosynthetic organisms and ultraviolet light having a light emission band in wavelengths of 300 to 380 nm emitted from the semiconductor layer.

In the photosynthesis inhibiting light source according to the first embodiment mentioned below, an example is described in which substantially white light is made by mixing violet light having a light emission band in wavelengths of 380 to 400 nm included in near-ultraviolet light with green light emitted from an fluorescent substance. However, the present invention is not necessarily limited to this combination, and may be free in how to combine them and free in what is selected from a plurality of kinds of fluorescent substances that emit light having specific wavelength regions as long as a combination is made so that light having at least one specific wavelength region serves as substantially white light by being mixed with violet light having a light emission band in wavelengths of 380 to 400 nm and as long as any combination is adopted except for a combination of blue light having a light emission peak in wavelengths of 430 to 490 nm and red light having a light emission peak in wavelengths of 640 to 680 nm, more preferably, except for a combination of blue light having a light emission peak in wavelengths of 430 to 490 nm and orange-to-red light having a light emission peak in wavelengths of 600 to 680 nm, still more preferably, except for red light having a light emission peak in wavelengths of 640 to 680 nm, very much more preferably, except for orange-to-red light having a light emission peak in wavelengths of 600 to 680 nm.

More specifically, substantially white light can also be made by mixing violet light having a light emission band in wavelengths of 380 to 400 nm with two kinds of rays of light, such as yellowish green light having a light emission peak in a wavelength of 565 nm and bluish green light having a light emission peak in a wavelength of 488 nm.

Additionally, in the photosynthesis inhibiting light source according to the second embodiment mentioned below, an example in which substantially white light is made by mixing blue light having a light emission peak in wavelengths of 430 to 490 nm and yellow light having a light emission peak in wavelengths of 570 600 nm together, both of which have a complementary relationship with each other, is described as a mixture example of rays of light of at least two kinds of specific wavelength regions emitted from fluorescent substances. However, the present invention is not necessarily limited to this combination, and may be free in how to combine them and free in what is selected from a plurality of kinds of fluorescent substances having specific wavelength regions as long as any combination is adopted except for a combination of blue light having a light emission peak in wavelengths of 430 to 490 nm and red light having a light emission peak in wavelengths of 640 to 680 nm both of which are turned into substantially white light by being mixed with each other, more preferably, except for a combination of blue light having a light emission peak in wavelengths of 430 to 490 nm and orange-to-red light having a light emission peak in wavelengths of 600 to 680 nm, still more preferably, except for red light having a light emission peak in wavelengths of 640 to 680 nm, very much more preferably, except for orange-to-red light having a light emission peak in wavelengths of 600 to 680 nm.

Substantially white light can also be made by a combination of three kinds of rays of light, such as blue-violet light having a light emission peak in a wavelength of 415 nm, bluish green light having a light emission peak in a wavelength of 493 nm, and yellowish green light having a light emission peak in a wavelength of 565 nm.

The following compounds can be used as fluorescent substances having light emission peaks in specific wavelength regions, respectively. Examples of fluorescent substances that emit green light include ZnS:Cu,Al; BaMgAl₁₀O₁₇:Eu,Mn; Si₆₋ₓAlₓOₓN₈₋ₓ:Eu; and Ca₃Sc₂Si₃O₁₂:Ce. Examples of fluorescent substances that emit blue light include BaMgAl₁₀O₁₇:Eu; (Sr, Ca, Ba, Mg)₁₀(PO₄)₆C₁₂:Eu; and LaAl(Si₆₋ₓAlₓ)N₁₀₋ₓOₓ:Ce. Examples of fluorescent substances that emit yellow light include (Y,Gd)₃Al₅O₁₂:Ce and Mx(Si,Al)₁₂OₓN₈₋ₓ:Eu. Examples of fluorescent substances that emit red light include Y₂O₂S:Eu and CaAlSiN₃:Eu.

In the fluorescent substances composed of the above-mentioned compounds, the peak wavelength of the fluorescent substance can be varied to some extent by varying the mixing ratio of source materials making up a compound.

Therefore, if an intermediate color (hereinafter, referred to “blue-green light”) between blue light and green light, for example, is intended to be emitted by using fluorescent substances, two kinds of methods can be adopted. One of the two methods is to make a fluorescent substance that emits blue-green light by varying the mixing ratio of source materials making up a fluorescent substance that emits blue light or making up a fluorescent substance that emits green light, thereby allowing one kind of fluorescent substance to emit blue-green light, whereas the other method is to use two kinds of fluorescent substances consisting of a fluorescent substance that emits blue light and a fluorescent substance that emits green light, thereby making the resulting mixed light into blue-green light.

Additionally, the intensity of light emitted from a fluorescent substance is proportional to the additive amount of the fluorescent substance, and therefore, if a plurality of fluorescent substances are used, the color of light emitted therefrom can be adjusted by varying the additive amount of each fluorescent substance.

In other words, if blue-green light is made by using a fluorescent substance that emits blue light and a fluorescent substance that emits green light, its bluish part can be strengthened by increasing the ratio of the fluorescent substance that emits blue light, whereas its greenish part can be strengthened by increasing the ratio of the fluorescent substance that emits green light.

Therefore, substantially white light can be made by mixing rays of light having various colors together according to a way in which the color of light emitted from a fluorescent substance is changed by varying the mixing ratio of source materials making up the fluorescent substance, or according to a way in which light having a desired color is emitted by appropriately combining a plurality of kinds of fluorescent substances that emit rays of light having different colors, respectively, or according to a way in which the intensity of light having a specific wavelength region is adjusted while adjusting the additive amount of a fluorescent substance, or according to an appropriate combination of these ways.

Whether substantially white light can be made by mixing rays of light having a plurality of kinds of colors together can be determined by examining whether a straight line obtained by plotting two points on a spectrum locus in a chromaticity diagram and by connecting the two points together is contiguous to or passes through an area showing substantially white light or examining whether a polygon obtained by plotting three or more points on a spectrum locus and by connecting these points together overlaps with an area showing substantially white light.

Additionally, a fluorescent substance that emits green light, a fluorescent substance that emits blue light, a fluorescent substance that emits yellow light, and a fluorescent substance that emits red light, each of which is used in photosynthesis inhibiting light sources according to the first and second embodiments of the present invention or is used in a photosynthesis inhibiting illuminating device according to the third embodiment, are not necessarily limited to the above-mentioned compounds. In the present invention, any compound may be used except for a combination of blue light having a light emission peak in wavelengths of 430 to 490 nm and red light having a light emission peak in wavelengths of 640 to 680 nm, more preferably, except for a combination of blue light having a light emission peak in wavelengths of 430 to 490 nm and orange-to-red light having a light emission peak in wavelengths of 600 to 680 nm, still more preferably, except for red light having a light emission peak in wavelengths of 640 to 680 nm, very much more preferably, except for orange-to-red light having a light emission peak in wavelengths of 600 to 680 nm.

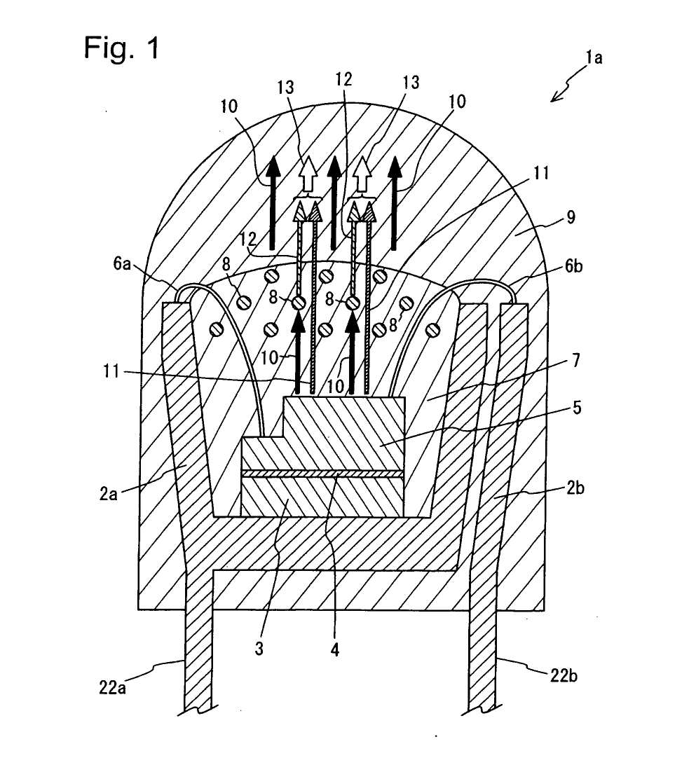

A photosynthesis inhibiting light source according to the first embodiment of the present invention will be described with reference to FIG. 1.

FIG. 1 is a sectional view of the photosynthesis inhibiting light source according to the first embodiment of the present invention.

As shown in FIG. 1, in the photosynthesis inhibiting light source 1a according to the first embodiment of the present invention, a semiconductor layer 5 that emits near-ultraviolet light is joined to an insulating substrate 3 disposed on the bottom surface of an electroconductive cup-like frame 2a through a buffer layer 4, and the semiconductor layer 5 and the upper end of the frame 2a are connected together by an electroconductive wire 6a, whereas the semiconductor layer 5 and the upper end of the frame 2b are connected together by an electroconductive wire 6b, and these are sealed by a sealing material 7.

The frames 2a and 2b between which the semiconductor layer 5 is sealed are contained in a synthetic-resin-made lens 9, thus forming the cannonball-shaped photosynthesis inhibiting light source 1a. Electroconductive legs 22a and 22b are extended from the electroconductive frames 2a and 2b, respectively.

Fluorescent substances 8 each of which emits green light having a light emission peak in wavelengths of 550 to 570 nm are embedded in the sealing material 7 in a dispersed state.

Referring to FIG. 1, a detailed description will be given of a mechanism in which substantially white light that inhibits and stunts the growth and propagation of photosynthetic organisms is emitted from the photosynthesis inhibiting light source 1a according to the first embodiment shown in FIG. 1.

In order to generate substantially white light that inhibits and stunts the growth and propagation of photosynthetic organisms from the photosynthesis inhibiting light source 1a according to the first embodiment, it is recommended to pass an electric current from the legs 22a and 22b to the frames 2a and 2b, respectively.

At this time, electric power is supplied from the frames 2a and 2b to the semiconductor layer 5 via the wires 6a and 6b, respectively, and, as a result, near-ultraviolet light 10 is emitted from the semiconductor layer 5.

Part of this near-ultraviolet light 10 strikes the fluorescent substances 8 embedded in the sealing material 7, and green light 12 having a light emission peak in wavelengths of 550 to 570 nm is emitted from each of the fluorescent substances 8.

Part of the near-ultraviolet light 10 emitted from the semiconductor layer 5 is emitted from the sealing material 7 to the lens 9 without being absorbed by the fluorescent substances 8. Violet light 11 having a light emission band in wavelengths of 380 to 400 nm is included in this near-ultraviolet light 10. The green light 12 emitted from the fluorescent substance 8 and the violet light 11 have a complementary relationship with each other, and therefore mixed light 13 formed of the violet light 11 and the green light 12 emitted from the photosynthesis inhibiting light source 1a is turned into substantially white light.

Both the green light 12 and the violet light 11 making up the substantially white mixed light 13 can hardly contribute to photosynthesis in an organism, and therefore, advantageously, the growth and propagation of photosynthetic organisms can be halted or inhibited.

Additionally, the mixed light 13 becomes substantially white light at this time, and therefore, advantageously, a to-be-illuminated target can be brightly illuminated.

Additionally, ultraviolet light having a light emission band in wavelengths of 300 to 380 nm that is included in near-ultraviolet light 10 emitted from the semiconductor layer 5 changes the structure of protein with which the surface of photosynthetic organisms is covered, and obstructs the replication of DNA of photosynthetic organisms. Therefore, this ultraviolet light can be safely used as a light source for illumination because this light does not exert an adverse influence upon the human body while having the effect of inhibiting and stunting the growth and propagation of photosynthetic organisms.

In other words, light emitted from the photosynthesis inhibiting light source 1a is substantially white light that does not impair the human body, and therefore, advantageously, this light can be used as, for example, illumination light in a cave through which sightseers walk.

Additionally, the photosynthesis inhibiting light source 1a according to the first embodiment achieves the effect of being capable of inhibiting and stunting the growth and propagation of photosynthetic organisms on a to-be-illuminated target by a combination of the effect of enabling the substantially white mixed light 13 to halt or inhibit the growth and propagation of photosynthetic organisms and the effect of enabling the ultraviolet light included in the near-ultraviolet light 10 to halt or inhibit the growth and propagation of photosynthetic organisms.

Therefore, advantageously, when the to-be-illuminated target is illuminated with light emitted from the photosynthesis inhibiting light source 1a, photosynthetic organisms can be prevented from newly growing or propagating on the to-be-illuminated target, and the ecosystem in the cave can be maintained suitably.

Although an example in which the fluorescent substances 8 are embedded in the sealing material 7 is mentioned in FIG. 1, the fluorescent substances 8 may be contained in the lens 9, or may be contained both in the sealing material 7 and in the lens 9. Alternatively, the fluorescent substances 8 may be allowed to adhere to the surface of the sealing material 7 or to the surface to the lens 9, for example, through a coating process. In any case, the same effect as the photosynthesis inhibiting light source 1a shown in FIG. 1 is achieved. The same applies to a photosynthesis inhibiting light source according to the second embodiment mentioned below.

Additionally, although an example in which the photosynthesis inhibiting light source 1a is used as a package type light source that can be mounted on a printed circuit board is mentioned in the first embodiment, the present invention is not limited to this. For example, SMD mounting may be adopted, or bare chip mounting in which the semiconductor layer 5 that emits near-ultraviolet light is mounted directly on a printed circuit board may be adopted. In this case, the fluorescent substances 8 are involved in a resin with which the semiconductor layer 5 is sealed, or are allowed to adhere thereto, and, as a result, the same process/effect as the photosynthesis inhibiting light source 1a shown in FIG. 1 can be achieved. The same applies to the photosynthesis inhibiting light source according to the second embodiment mentioned below.

### Embodiment 2

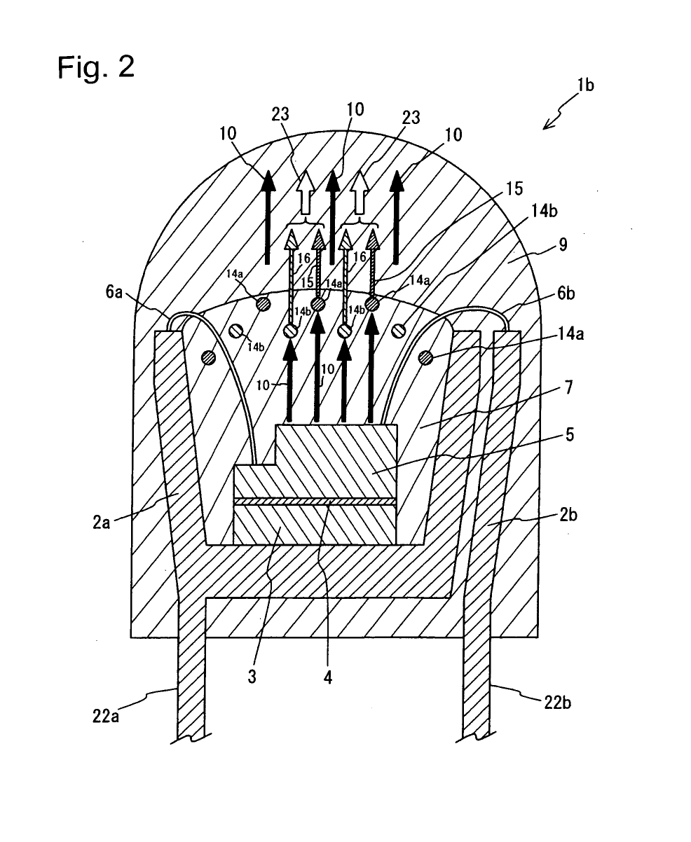

Next, the photosynthesis inhibiting light source according to the second embodiment of the present invention will be described in detail with reference to FIG. 2.

FIG. 2 is a sectional view of the photosynthesis inhibiting light source according to the second embodiment of the present invention. The same numeral is given to the same component as in FIG. 1, and a description of its structure is omitted. The photosynthesis inhibiting light source 1b according to the second embodiment is substantially the same in structure as the photosynthesis inhibiting light source 1a according to the first embodiment mentioned above, and, in the second embodiment, a description will be given with emphasis on differences with the photosynthesis inhibiting light source 1a according to the first embodiment.

As shown in FIG. 2, the photosynthesis inhibiting light source 1b according to the second embodiment is characterized by including two kinds of fluorescent substances 14a and 14b inside the sealing material 7, instead of the fluorescent substances 8 of the photosynthesis inhibiting light source 1a according to the first embodiment mentioned above.

Additionally, in the photosynthesis inhibiting light source 1b according to the second embodiment, each of the fluorescent substances 14a embedded in the sealing material 7 is a fluorescent substance that emits blue light having a light emission peak in wavelengths of 430 to 490 nm by being excited by near-ultraviolet light 10 emitted from the semiconductor layer 5. Each of the fluorescent substances 14b is a fluorescent substance that emits yellow light having a light emission peak in wavelengths of 570 to 600 nm by being excited by near-ultraviolet light 10 emitted from the semiconductor layer 5.

In the photosynthesis inhibiting light source 1b according to the second embodiment shown in FIG. 2, electric power is supplied to the semiconductor layer 5, and, as a result, near-ultraviolet light 10 is emitted from the semiconductor layer 5, then strikes the fluorescent substances 14a and 14b embedded in the sealing material 7, then excites these substances, and generates blue light 15 having a light emission peak in wavelengths of 430 to 490 nm and yellow light 16 having a light emission peak in wavelengths of 570 to 600 nm.

Blue light 15 emitted from the fluorescent substances 14a and yellow light 16 emitted from the fluorescent substances 14b have a complementary relationship with each other, and therefore mixed light 23 obtained by mixing these rays of light together is substantially white light, and, advantageously, can be used as a light source for illumination.

As described above, when ultraviolet light having a light emission band in wavelengths of 300 to 380 nm included in near-ultraviolet light 10 is emitted from the sealing material 7 without being absorbed by the fluorescent substances 14a or the fluorescent substances 14b, this ultraviolet light has the effect of inhibiting and stunting the growth and propagation of photosynthetic organisms without exerting an adverse influence upon the human body.

Therefore, advantageously, the photosynthesis inhibiting light source 1b according to the second embodiment prevents photosynthetic organisms from newly growing or propagating on a to-be-illuminated target, and, as a result, the ecosystem in the cave can be maintained suitably, and the to-be-illuminated target can be brightly illuminated in the same way as the photosynthesis inhibiting light source 1a according to the first embodiment.

In the photosynthesis inhibiting light sources 1a and 1b according to the first and second embodiments, an example in which the single semiconductor layer 5 is disposed in the frame 2a is mentioned. However, without being limited to this example, bare chip mounting in which a plurality of semiconductor layers 5 each of which emits near-ultraviolet light 10 are mounted on a printed circuit board may be adopted, or SMD mounting may be adopted.

In this case, it is possible to achieve the effect of being capable of providing the photosynthesis inhibiting light sources 1a and 1b each of which has higher intensity of illumination.

### Embodiment 3

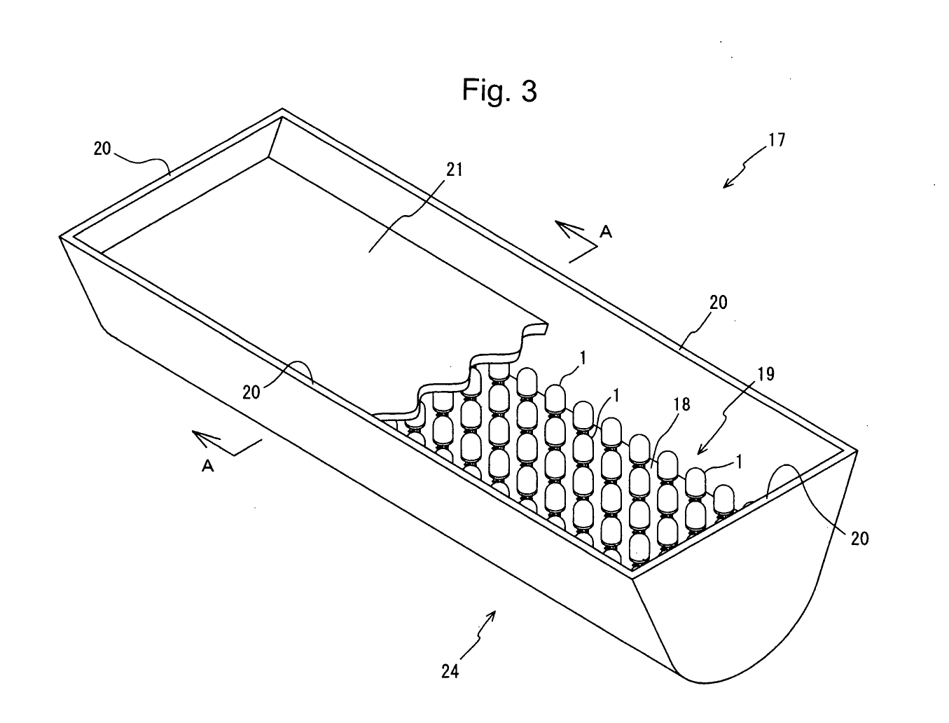

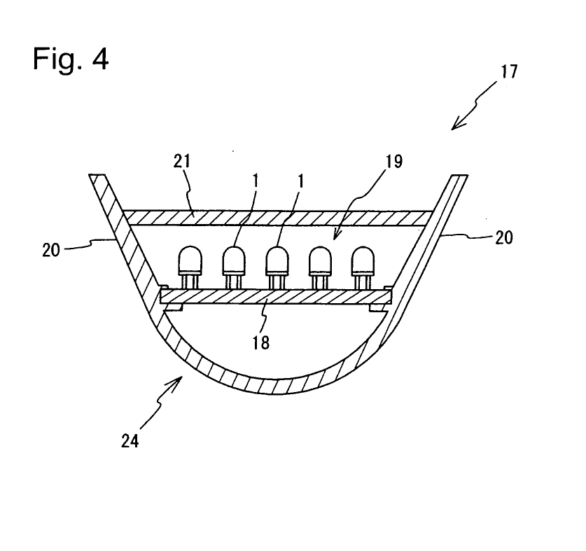

Lastly, the photosynthesis inhibiting illuminating device according to the third embodiment of the present invention will be described in detail with reference to FIG. 3 and FIG. 4.

FIG. 3 is a conceptual diagram of the photosynthesis inhibiting illuminating device according to the third embodiment of the present invention, and FIG. 4 is a sectional view along line A-A of FIG. 3. The same numeral is given to the same component as in FIGS. 1 and 2, and a description of its structure is omitted.

The photosynthesis inhibiting illuminating device according to the third embodiment uses the photosynthesis inhibiting light sources 1a and 1b according to the first and second embodiments, and the photosynthesis inhibiting light sources 1a and 1b are represented generically as the photosynthesis inhibiting light source 1 in FIG. 3.

As shown in FIGS. 3 and 4, the photosynthesis inhibiting illuminating device 17 according to the third embodiment is structured such that a planar light source 19 in which a plurality of photosynthesis inhibiting light sources 1 are mounted on a flat printed circuit board 18 is formed, such that the planar light source 19 is contained in a housing 24 that has reflectors 20 at its four sides, respectively, and such that a place in a direction in which rays of light of the photosynthesis inhibiting light sources 1 are emitted is covered with an optical diffuser 21 formed of, for example, a microlens array.

For example, an arm may be provided to support the photosynthesis inhibiting illuminating device 17 according to the third embodiment although this arm is not specifically shown in FIGS. 3 and 4.

The photosynthesis inhibiting illuminating device 17 thus structured according to the third embodiment uses the photosynthesis inhibiting light sources 1a and 1b according to the first and second embodiments mentioned above, and has the same process/effect as the photosynthesis inhibiting light sources 1a and 1b according to the first and second embodiments.

Additionally, the reflector 20 has the process of preventing light emitted from the photosynthesis inhibiting light source 1 from diffusing in the planar direction of the printed circuit board 18 and hence from attenuating.

Additionally, the optical diffuser 21 has the process of diffusing light emitted from the photosynthesis inhibiting light source 1.

Therefore, the provision of the reflector 20 and the optical diffuser 21 at the planar light source 19 makes it possible to achieve the effect of being capable of illuminating a desired spot while diffusing light emitted from the photosynthesis inhibiting light source 1 in the radiative direction and while preventing light emitted from the planar light source 19 from attenuating in the planar direction.

Additionally, the mounting of the plurality of photosynthesis inhibiting light sources 1 on the printed circuit board 18 makes it possible to heighten the intensity of substantially white light emitted from the photosynthesis inhibiting light sources 1 to the to-be-illuminated target, which can hardly contribute to the growth and propagation of photosynthetic organisms, and the intensity of ultraviolet light included in near-ultraviolet light 10, which inhibits and stunts the growth and propagation of photosynthetic organisms, and hence makes it possible to achieve the effect of inhibiting and stunting the growth and propagation of photosynthetic organisms and the effect of increasing the illumination effect.

In the third embodiment, an example is mentioned in which the planar light source 19 is formed by mounting the plurality of photosynthesis inhibiting light sources 1 on the flat printed circuit board 18. However, the planar light source 19 may be formed such that, for example, a plurality of semiconductor layers 5 that emit near-ultraviolet light 10 are mounted on the printed circuit board according to bare chip mounting, and the fluorescent substance 8 or both of the fluorescent substances 14a and 14b are contained in or are allowed to adhere to either its sealing material or its lens or both of the sealing material and the lens.

This case makes it possible to achieve the effect of being capable of forming the planar light source 19 out of one photosynthesis inhibiting light source 1.

In the photosynthesis inhibiting illuminating device 17 according to the third embodiment, an example is mentioned in which the photosynthesis inhibiting light source 1 is provided with the fluorescent substance 8 or the fluorescent substances 14a and 14b. However, the fluorescent substance 8 or the fluorescent substances 14a and 14b may be contained in the optical diffuser 21 or may be allowed to adhere to the surface of the optical diffuser 21.

This case makes it possible to achieve the effect of being capable of produce the photosynthesis inhibiting illuminating device 17 according to the third embodiment by use of ready-made light sources that emit near-ultraviolet light 10.

As a result, the present invention has the effect of being capable of greatly reducing the production cost of the photosynthesis inhibiting illuminating device 17 according to the third embodiment.

### INDUSTRIAL APPLICABILITY

As described above, the present invention is a photosynthesis inhibiting light source that emits substantially white light that does not exert an adverse influence on the human body while inhibiting/stunting the growth and propagation of photosynthetic organisms, and is a photosynthesis inhibiting illuminating device that uses this light source, and is usable in the field relative to an illuminating device to be installed at a place at which photosynthetic organisms, such as seed plants, fern, moss, algae, fungi, and bacilli, are not desired to grow and propagate.

1. A photosynthesis inhibiting light source comprising:
a semiconductor layer that emits near-ultraviolet light and a fluorescent substance that emits green light by being excited by the near-ultraviolet light, the green light having a light emission peak in wavelengths of 550 to 570 nm and hardly contributing to photosynthesis,
wherein the near-ultraviolet light includes ultraviolet light having a light emission band between a wavelength of 300 and a wavelength of 380 nm that hardly contributing to photosynthesis and violet light having a light emission band between a wavelength of 380 and a wavelength of 400 nm that hardly contributing to photosynthesis,
wherein substantially white light is made by mixing the near-ultraviolet light and the green light together, and
wherein the substantially white light does not include red light having a light emission peak in wavelengths of 640 to 680 nm.

2. (canceled)

3. (canceled)

4. The photosynthesis inhibiting light source according to claim 1, wherein the fluorescent substances are a fluorescent substance that has a light emission peak in wavelengths of 430 to 490 nm and that emits blue light and a fluorescent substance that has a light emission peak in wavelengths of 570 to 600 nm and that emits yellow light, respectively.

5. A photosynthesis inhibiting illuminating device comprising at least one photosynthesis inhibiting light source according to claim 1.

6. The photosynthesis inhibiting illuminating device according to claim 5, characterized by further comprising an optical diffuser disposed on a side toward which light of the photosynthesis inhibiting light source is emitted.

7. The photosynthesis inhibiting illuminating device according to claim 6, characterized in that the fluorescent substance is contained in or is allowed to adhere to the optical diffuser.
